(19) United States
(12) Patent Application Publication
(10) Pub. No.: US 2026/0093976 A1
(43) Pub. Date: Apr. 2, 2026

(54) FAULT-AWARE TRAINING TO SALVAGE AI ACCELERATORS

(71) Applicant: ATI Technologies ULC, Thornhill (CA)

(72) Inventor: Ihab AMER, Thornhill (CA)

(21) Appl. No.: 18/900,435

(22) Filed: Sep. 27, 2024

(51) Int. Cl. G06N 3/08; G06F 30/327; G06N 3/0475

(52) U.S. Cl. CPC G06N 3/08; G06F 30/327; G06N 3/0475

(57) ABSTRACT

Embodiments herein describe a method for generating multiple neural network model approximations of a compute engine of an integrated circuit (IC) including at least one fault, matching a fault map loaded to the IC with one of the multiple neural network model approximations, and loading a matched neural network model approximation to the IC. The compute engine is a multiply-accumulate (MAC) unit incorporated within an artificial intelligence (AI) accelerator. The multiple neural network model approximations are generated when the compute engine transitions into an approximate mode. In the approximate mode, a first set of operations are substituted for a second set of operations, where the first set of operations are higher precision arithmetic operations and the second set of operations are lower precision arithmetic operations.

### TECHNICAL FIELD

Examples of the present disclosure generally relate to integrated circuits, and, in particular, to performing fault-aware training to salvage artificial intelligence accelerators incorporated in integrated circuits.

### BACKGROUND

In the semiconductor manufacturing industry, yield improvement is a factor in ensuring profitability and competitiveness. As integrated circuits (ICs) become increasingly complex, the likelihood of defects during production rises, leading to lower yields and higher costs. Traditional methods of addressing defects, such as redesigning chips or improving fabrication processes, can be time-consuming and expensive. An innovative approach to yield improvement is IP (Intellectual Property) harvesting or salvaging, which involves repurposing defective chips by identifying and utilizing their functional parts. By leveraging advanced machine learning models and fault-tolerant architectures, it is possible to bypass defective areas and harness the computational capabilities of otherwise discarded chips, thereby increasing overall yield and reducing waste.

### SUMMARY

One embodiment described herein is a method for generating multiple neural network model approximations of a compute engine of an integrated circuit (IC) including at least one fault, matching a fault map loaded to the IC with one of the multiple neural network model approximations, and loading a matched neural network model approximation to the IC. The compute engine is a multiply-accumulate (MAC) unit incorporated within an artificial intelligence (AI) accelerator. The multiple neural network model approximations are generated when the compute engine transitions into an approximate mode. In the approximate mode, a first set of operations are substituted for a second set of operations, where the first set of operations are higher precision arithmetic operations and the second set of operations are lower precision arithmetic operations.

One embodiment described herein is a method for operating an integrated circuit (IC) having a fault and loaded with a matched neural network model approximation that is selected by transitioning a compute engine of the IC into an approximate mode and substituting a first set of operations for a second set of operations.

One embodiment described herein is a system including at least one physical processor and physical memory comprising computer-executable instructions that, when executed by the physical processor, cause the physical processor to generate multiple neural network model approximations of a compute engine of an integrated circuit (IC) including at least one fault, load a fault map of the IC, match the fault map of the IC with one of the multiple neural network model approximations, and load a matched neural network model approximation to the IC.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 illustrates an integrated circuit (IC) including an artificial intelligence (AI) accelerator, according to an example.

FIG. 2 illustrates the AI accelerator of FIG. 1 including an array of multiply-accumulate (MAC) units, according to an example.

FIG. 3 illustrates a MAC unit of FIG. 2 transitioning into an approximate mode, according to an example.

FIG. 4 illustrates the training phase and the inference phase for deploying ICs running pre-trained models approximating computations, according to an example.

FIG. 5 illustrates a method for running an approximated equivalent model in the ICs, according to an example.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the embodiments herein or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

Semiconductor manufacturing involves complex processes aimed at producing integrated circuits (ICs) with high reliability and performance. One of the challenges in this field is achieving a high yield rate, which refers to the percentage of fully functional chips produced from the total number of fabricated chips. Low yield rates can lead to financial losses and inefficiencies in production. Traditional approaches to improving yield focus on enhancing manufacturing processes, reducing defects, and optimizing equipment performance. However, these methods may not fully leverage the potential of intellectual property (IP) embedded within the semiconductor design and fabrication stages.

IP in semiconductor manufacturing includes design libraries, process technologies, layout methodologies, and circuit architectures developed by semiconductor companies. These IPs are beneficial for implementing specific functionalities, ensuring performance targets, and maintaining competitive advantages in the market. Despite advancements in semiconductor technology, there remains a need for innovative solutions to maximize chip yield effectively. The utilization of IP resources throughout the manufacturing process represents a valuable yet underexplored area for yield improvement. The example embodiments propose a novel approach to improving chip yield through IP harvesting by utilizing defective MAC units (i.e., including faults) in artificial intelligence (AI) accelerators without comprising reliability of results or incurring tedious re-training costs per defective part.

Detecting a faulty IC, performing fault modeling, and engaging in fault-aware training based on simulated fault maps are valuable processes in ensuring the reliability and robustness of ICs. Detecting a faulty IC may include functional testing, parametric testing, built-in-self-test (BIST), and visual inspection. For functional testing, predefined input signals (e.g., test vectors) are applied to the IC and the outputs are observed. Deviations from expected outputs indicate potential faults. For parametric testing, parameters such as voltage, current, and timing characteristics are measured to ensure they are within specified ranges. Thresholds are set for the parameters and any deviations may indicate a fault. BIST involves incorporating self-test circuits within the IC to perform testing autonomously.

IC fault modeling involves the process of simulating and analyzing how faults within an IC affect its performance and functionality. IC fault modeling involves identifying potential faults, performing fault injection, and performing fault detection and diagnosis. Common faults include stuck-at faults, bridging faults, open faults, and transient faults. Stuck-at faults occur when a signal line is stuck at a logical high or a logical low. Bridging faults occur when there is an unintended connection between two signal lines. Open faults occur when a connection is broken and transient faults occur when temporary errors are detected due to, e.g., external interference. Faults can originate from manufacturing defects, material imperfections, design errors, or environmental factors, such as temperature variations.

Fault-aware training may be performed based on simulated fault maps. In one example, fault simulation tools are used to create maps that highlight areas of the IC susceptible to various faults. These maps are analyzed to understand the impact and likelihood of different faults. Artificial intelligence (AI) and machine learning (ML) can be employed to collect data from simulated fault maps and real-world testing, identify key features from the data that indicate the presence and type of faults (i.e., feature extraction), and machine learning models (e.g., neural networks, decision trees) are trained using labeled data (faulty vs. non-faulty) to predict faults. Algorithms can be developed that can adapt to the presence of faults, maintaining functionality despite faults. The trained models can be validated using additional simulations and real-world testing to ensure their accuracy and robustness. Thus, detecting a faulty IC, performing fault modeling, and engaging in fault-aware training based on simulated fault maps involves a comprehensive approach that includes testing, simulation, and machine learning. This approach ensures that ICs are reliable and robust, even in the presence of potential faults. However, such fault map approach has its limitations.

In semiconductor manufacturing, improving yield through IP harvesting or salvaging involves leveraging existing design and technology elements from partially functional chips to enhance the overall yield and efficiency of new semiconductor products. Manufacturers have been pursuing options to salvage components within a wide variety of system-on-chips (SOC's). For example, it is a common practice to salvage central processing (CPU) chips with defective cores, or graphics processing unit (GPU) chips with defective compute units. The commonly known harvesting mechanisms are performed at the IP level of granularity. This means that a chip with a defect in an IP is shipped with defeatured functionalities that correspond to this particular IP. Some IPs are so valuable that defeaturing their functionalities deems the chip quite unusable. If any of these ICs have defective artificial intelligence (AI) accelerator units, using them with defeatured machine learning (ML) inference functionalities is not a viable option. If a device has a large portion of its die area devoted to an AI accelerator unit, then there are potential recovery opportunities to gain back yield with AI accelerator unit salvaging.

Every IC goes through a well-designed test coverage to detect various types of defects. These manufacturing tests are thorough and detailed enough to identify defective tiles within the AI accelerator unit and to mark them in the device's memory. This opens the door to designing fault tolerant software that can flexibly avoid defective units without discarding the hosting chip, leading to yield improvements with little to no impact on performance and model accuracy.

The example embodiments present a way to utilize AI accelerators with defects or faults without compromising the reliability of the results and without incurring tedious retraining costs. Pruning the node that is associated to a defective unit is an aggressive resolution of the problem, which leads to drops in model's accuracy. Ideally, and to avoid retraining, a fault-aware training mechanism can be used, which accounts for the fault in the forward pass to develop robustness against it.

Injecting simulated faults during fault-aware training represents risk to hardware vendors. On the other hand, having pre-trained model variations that account for every possible real defect is unpractical, even if restricted to single-defect salvaging. For example, an array of 4×20 tiles will need 80 pre-trained models, where each assumes a single defective tile. To limit the number of pre-trained model variations, accounting for faults at a coarser level of granularity may be considered. For example, if a whole faulty column (or tile cluster) is accounted for when one unit or more fail in that column, then an array of 4×20 tiles will require 20 pre-trained models, while if the process goes even coarser (e.g., 4 columns), then this leads to only 5 model variations.

The problem with fault-accounting at a coarser level of granularity is that it is difficult to regain the lost accuracy that comes with it. For example, if pruning is to be used to account for faults, training a model that is stripped off four columns of neurons makes it quite challenging to preserve accuracy.

Accordingly, instead of aggressively pruning out neurons/computations that map to defective units, the example embodiments suggest performing an approximated equivalent to it, in which case, pre-training at a coarse level of granularity will have a higher chance to preserve accuracy. The example embodiments propose that when a multiply-accumulate (MAC) unit is identified as being defective, the MAC unit itself, its column, or possibly a cluster of m×n units that includes it, is forced to operate in an approximate mode. In the approximate mode, the logic inside the unit is utilized differently, where, e.g., logic that is originally intended to handle least significant portions of calculations can be used to replicate logic that handles most significant portions of calculations, and hence a guarantee to correct single errors to a nearest certain level of precision is preserved. Approximate computing leverages the idea that not all computations need to be exact, especially in applications like neural networks where slight inaccuracies can be tolerated.

Another possibility is to replace computations that execute on defective circuitry with semi-equivalent ones that execute on functioning circuitry. These can be used as approximate equivalents to each other. During training, the same approximation is emulated in the forward path, to allow the model to adjust to the error incurred in a deterministic manner that is pre-qualified a priori. During deployment, every defective chip runs a model that is pre-trained to approximate the computation of its defective unit(s), which are stored on the device's memory as a defect map, dodging or avoiding or bypassing the circuit faults. By incorporating fault-aware training and approximate computing techniques, approximated neural networks can be created that are resilient to hardware faults in MAC units or AI accelerators. This approach allows for the effective salvaging of partially defective hardware, improving yield and extending the useful life of AI accelerators.

Therefore, the example embodiments present innovative approaches to allow practical AI accelerator salvaging without the need for tedious per-chip retraining. One approach is a hardware fault-tolerant approach and another approach is a software fault-tolerant approach. Both proposed methodologies allow dynamic adaptation to aging defects, leading to prolonged device lifetime.

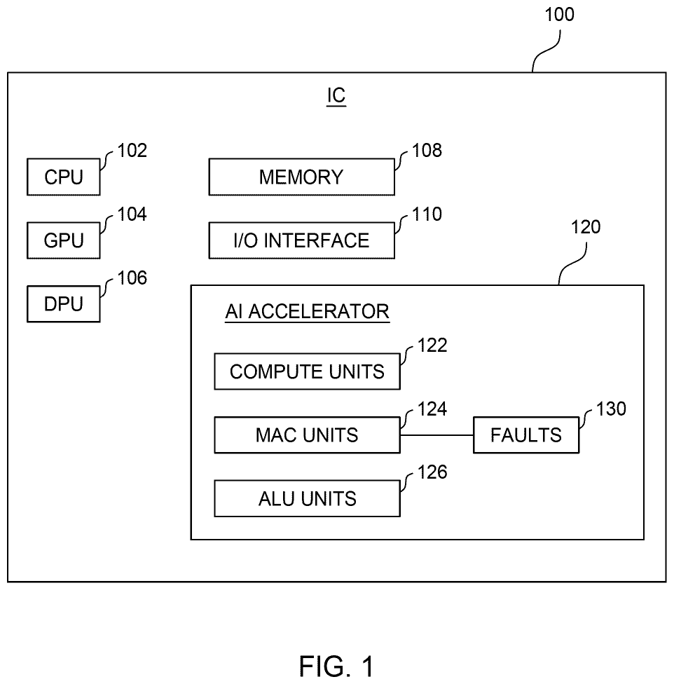

FIG. 1 illustrates an integrated circuit (IC) including an artificial intelligence (AI) accelerator, according to an example.

An IC 100 may include a wide range of electronic components or functional blocks, each serving specific functions. For example, the IC 100 may include a central processing unit (CPU) 102, a graphics processing unit (GPU) 104, and a data processing unit (DPU) 106. The IC 100 may also include a memory 108 and an input/output (I/O) interface 110. The IC may also be referred to as a microchip or simply a chip, and is a miniaturized electronic circuit that consists of various components integrated onto a single semiconductor substrate. The IC 100 may further include an AI accelerator 120. The AI accelerator 120 is designed to enhance the performance of AI and machine learning (ML) workloads, providing faster computation and lower power consumption compared to general-purpose processors.

The AI accelerator 120 may include compute units 122, multiply-accumulate (MAC) units 124 forming a MAC array, and arithmetic logic units (ALUs) 126. The MAC unit 124 is a specialized hardware component within the IC 100 designed to perform multiplication and accumulation operations efficiently. The MAC unit 124 may also be referred to generally as a compute engine. These operations are fundamental to many digital signal processing (DSP) tasks and are used in ML and AI applications.

The multiplication operation multiplies two input values, typically represented as integers or floating-point numbers. The accumulation operation involves adding the product of the multiplication to an accumulator, which stores the intermediate results of multiple operations. This allows for the continuous accumulation of products, which is valuable for various computational tasks. Neural network operations, particularly in deep learning, involve a significant number of multiply-accumulate operations. For example, in a convolutional layer, the MAC unit is used to perform the dot product of the filter weights and input data. MAC units enable efficient implementation of matrix multiplications, which are core to many AI algorithms. The AI accelerator 120 integrates the MAC units 124 to handle large-scale computations for training and inference in neural networks. The MAC units 124 may experience faults 130, as described below.

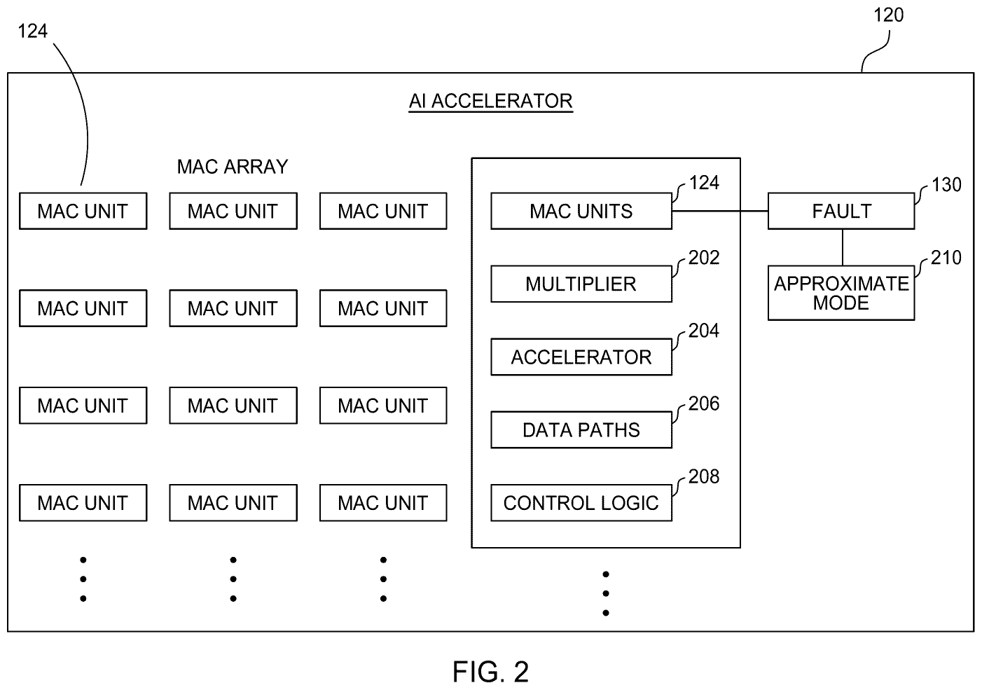

FIG. 2 illustrates the AI accelerator of FIG. 1 including an array of multiply-accumulate (MAC) units, according to an example.

The AI accelerator 120 may include an array of MAC units 124. A MAC unit 124 may include a multiplier 202, an accelerator 204, data paths 206, and control logic 208. The control logic 208 of the MAC unit 124 manages the flow of data and the sequence of operations. The operations may include loading inputs, performing multiplication, accumulating results, and handling outputs. This may involve a combination of registers, multipliers, adders, and a finite state machine (FSM) to manage the control signals and operational flow.

When a fault 130 is detected in the MAC unit 124, the MAC unit may transition into an approximate mode 210. The fault 130 may be referred to as an IC fault. The fault 130 refers to any defect or error within the IC 100 that causes it to malfunction or deviate from its intended operation. Common faults include stuck-at faults, bridging faults, open faults, and transient faults. Stuck-at faults occur when a signal line is stuck at a logical high or a logical low. Bridging faults occur when there is an unintended connection between two signal lines. Open faults occur when a connection is broken and transient faults occur when temporary errors are detected due to, e.g., external interference. Faults can originate from manufacturing defects, material imperfections, design errors, or environmental factors, such as temperature variations.

Fault modeling and mitigation can be employed to ensure the reliability and performance of the IC 100. In one example, when a fault 130 is detected in a MAC unit 124, the MAC unit 124 may transition into an approximate mode 210. In particular, an approximated pre-trained neural network model is used when the approximate mode 210 is triggered. A pre-trained neural network model refers to a machine learning model trained to approximate the behavior of a faulty IC or specific fault conditions. This model learns from data collected from various fault scenarios and can predict the behavior of the IC under new or unseen fault conditions. The pre-trained neural network model is an approximated model allowing the IC 100 to operate in the approximate mode 210, as described below.

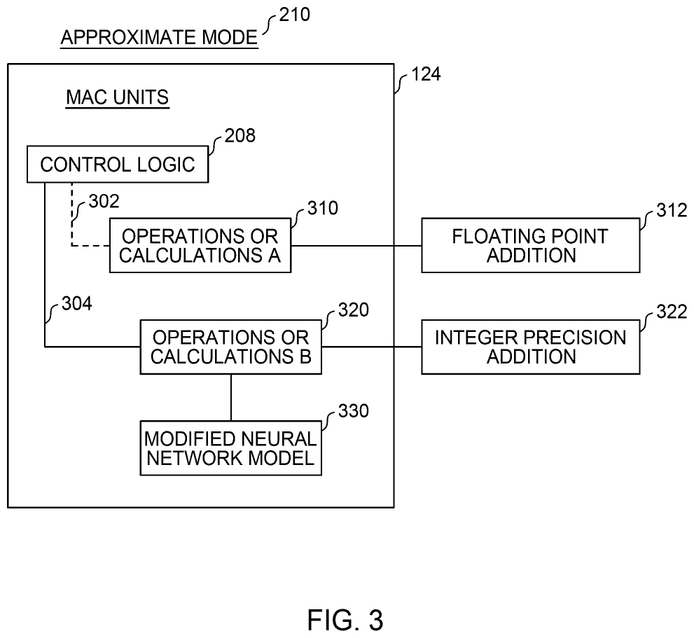

FIG. 3 illustrates the MAC unit of FIG. 2 transitioning into an approximate mode, according to an example.

The MAC unit 124 includes two traditional operations, that is, a multiply operation and an accumulate operation. A neural network may be used to perform the multiply and accumulate operations. The neural network includes an input layer, hidden layers, and an output layer. The input layer receives the inputs that are, e.g., numbers to be multiplied. The hidden layers capture the complexity of the multiplication and accumulation processes. The output layer produces a single value representing the result of the multiply-accumulate operation.

However, if faults are detected in the MAC unit 124, the MAC unit 124 transitions to the approximate mode 210. In the approximate mode 210, an approximated equivalent model of the MAC unit 124 is created. In other words, if the MAC unit 124 is determined or identified to be defective, the MAC unit 124 itself is forced to transition to the approximate mode 210. In the approximate mode 210, the logic inside the MAC unit 124 is utilized differently, where, e.g., logic that is originally intended to handle least significant portions of calculations is now used to replicate logic that handles most significant portions of calculations, and hence a guarantee to correct single errors to a nearest certain level of precision is preserved.

The approximated equivalent model is a neural network model where certain neurons or columns of neurons or combination of neurons from different columns are modified or adjusted or altered. In other words, neurons of neural network models or modified or adjusted or refined to be approximations or equivalents of certain computations in the MAC unit 124. The modifications pertain to changing or modifying or altering certain computations in the MAC unit 124 that may trigger the fault 130 to provide for an equivalent or approximated computation. Thus, one operation or one set of operations can be substituted or replaced or swapped for another operation or set of operations. Approximate computing leverages the idea that not all computations need to be exact, especially in applications like neural networks where slight inaccuracies can be tolerated.

For example, the control logic 208 of the MAC unit 124 may perform various operations. In one instance, the control logic 208 performs operations or calculations 310. The operations or calculations 310 (operations A) may be performing a floating point addition 312. The floating point addition 312 is a numerical operation that involves adding two floating point numbers, which are numbers represented in a format that can support a wide range of values. In one non-limiting example, the floating point addition 312 provides a result as 537.64598. The floating point addition 312 may be represented by a neuron in a neural network model or a column of neurons in a neural network model. If a fault is detected in the MAC unit 124 performing the floating point addition 312, instead of discarding the MAC unit 124 as it includes a fault, the operations or calculations 310 may be replaced or swapped or substituted with operations or calculations 320 (operations B). The operations or calculations 320 may be performing an integer precision addition 322. The integer precision addition 322 is an operation that involves adding two integer values together. Unlike the floating point addition 312, which handles a wide range of values with varying levels of precision, the integer precision addition 322 deals with whole numbers only, providing an integer result without the complications of fractional components. In one non-limiting example, the integer precision addition 322 provides the result as 537 only, without the fractional component 0.64598. Thus, the first set of operations are higher precision arithmetic operations (e.g., resulting in value 537.64598) and the second set of operations are lower precision arithmetic operations (e.g., resulting in value 537). However, such approximation is acceptable in maintaining the accuracy of the neural network model.

Therefore, the control logic 208 of the MAC unit 124 transitions from performing the floating point addition 312 (connection 302) to performing integer precision addition 322 (connection 304) when a fault is detected in the MAC unit 124. The integer precision addition 322 replaces the floating point addition 312 in a modified neural network model 330. The modified neural network model 330 thus includes an equivalent or approximated or comparable version of the computation (i.e., 537 vs 537.64598). This results in pre-training at a coarse level of granularity that will have a higher chance of preserving accuracy, despite the detected fault. In other words, the accuracy of the pre-trained neural network model remains acceptable even though certain neurons within the pre-trained neural network model have been replaced or swapped or substituted with equivalent or approximated or comparable neurons including slightly different computations.

Substituting the floating point addition 312 with integer precision addition 322 is one example. In another example, a full precision multiplication can be substituted with a low precision multiplication. Instead of implementing a floating point multiplication, a fixed point multiplication may be employed. In another example, a complex activation function may be substituted for a simpler activation function. Instead of using a sigmoid activation function, a hard sigmoid approximation may be employed. In yet another example, an exact convolution may be substituted for an approximate convolution. Any types of substitutions or replacements may take place to create multiple approximated models.

When multiple approximations are performed and such multiple approximations are used for re-training purposes, one advantage is preparing a response to a potential fault that has a bounded impact on the resulting error. In other words, if nothing is done, and an error comes along, the error is accepted and it is anticipated that the process will clean itself up. Overlooking such error may work. However, a lower boundary is not present. Thus, it is not known how adverse the impact of the error will be on the system. For example, if the error occurs in a critical calculation or significant bit, it may cause the system to hang up or break, and provide unsuitable or erroneous results or not converge. Therefore, to avoid such situation, the example embodiments run several approximations where it is anticipated that such approximations will dodge the effects of such overlooked error. If an approximation is discovered that dodges that overlooked error, then the system will not face undeterministic behaviors because the system discovered or found the approximation that is not going to trigger the overlooked error. As such, the results will now be deterministic because the model has been pre-trained with this approximation and the results of such approximation were accepted. The error is avoided or dodged and the impact of the approximation is known a priori. Stated differently, it is a deterministic outcome of this response to the error rather than a non-deterministic outcome.

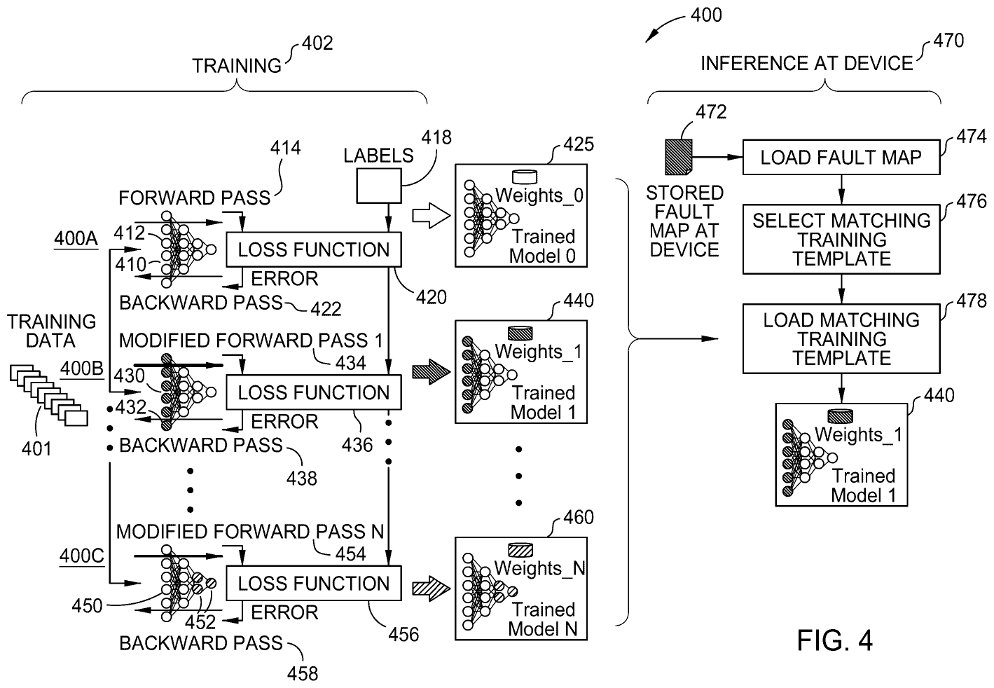

FIG. 4 illustrates the training phase and the inference phase for deploying integrated circuits (ICs) running pre-trained models approximating computations, according to an example.

In machine learning (ML) and artificial intelligence (AI), the machine learning workflow 400 can be broadly categorized into two main phases, that is, a training phase 402 and an inference phase 470. The goal of the training phase 402 is to build or train a model by learning from a dataset 401 (also referred to as training data). During this phase, the model iteratively adjusts its parameters to minimize errors and improve performance. The training phase 402 includes data collection and pre-processing, model selection (e.g., neural network), training using, e.g., optimization algorithms, and validation. The inference phase 470 involves using the trained model to make predictions or decisions based on new, unseen data. This phase occurs after the model has been fully trained and evaluated. The inference phase 470 includes deployment, prediction, post-processing, and monitoring. Thus, the training phase 402 focuses on building and refining the model using historical data and the inference phase 470 involves using the trained model to make predictions on new data.

When no fault is detected in an IC, the machine learning workflow 400A outputs a neural network model 425.

The neural network model 410 (original network) includes a plurality of neurons 412.

A forward pass 414 feeds the neural network model 410 with the dataset 401. The forward pass involves calculating the output of a neural network by passing the input data through each layer of the network. The forward pass process involves input data (i.e., features) fed into the neural network. For each layer in the network, the input data is transformed through the layer's weights, biases, and activation functions. The final layer produces the network's output, which could be a prediction for regression, class probabilities for classification, etc.

The output is fed into a loss function 420. A loss function (also known as a cost function or objective function) is a component used during the training phase 402. The loss function 420 measures how well the model's predictions match the actual target values. In other words, the loss function 420 quantifies the difference between the predicted outputs and the true outputs (targets). The labels 418 are the actual target values or correct answers associated with each input from the dataset 401. During the training phase 402, the labels 418 are used by the loss function 420 to calculate the error or difference between the model's predictions and the true values.

The goal of training a model is to minimize the loss function 420, thereby improving the model's accuracy and performance. The choice of loss function depends on the type of problem (e.g., regression, classification) and the specific characteristics of the data. For regression problems, the mean square error (MSE) or the mean absolute error (MAE) may be used. For classification problems, a binary cross-entropy or log loss may be used. During training, an optimization algorithm (e.g., gradient descent) is used to minimize the loss function. This involves computing the gradient (partial derivatives) of the loss function with respect to the model parameters and updating the parameters in the direction that reduces the loss.

The errors from the loss function 420 are back propagated to the neural network model 410. The backward pass 422 involves calculating the gradients of the loss function 420 with respect to each weight and bias in the network, and then updating these parameters to minimize the loss. The backward pass process involves calculating the loss (error) using a loss function, comparing the network's output from the forward pass to the actual target values, and using backpropagation to compute the gradients of the loss with respect to each parameter in the network.

After the layer-wise gradient computation, the weights and biases are updated using an optimization algorithm (e.g., gradient descent). Stated differently, the loss is propagated back through the network, gradients of the loss with respect to each parameter are computed, and parameters (weights and biases) are updated to minimize the loss. In neural networks, weights are the parameters that are learned during the training process. Weights determine the strength and direction of the connection between neurons in adjacent layers of the network. Each weight is a numerical value that influences how input data is transformed as it passes through the network.

The forward pass 414, the loss function 420, and the backward pass 422 work together to enable the neural network model 410 to learn from the dataset 401 and improve its performance. The forward pass 414 calculates the output of the network and provides predictions based on the input data (or dataset 401). The loss function 420 measures the discrepancy between the predicted output and the actual target values, quantifying the model's performance. The backward pass 422 computes the gradients of the loss function 420 with respect to model parameters and updates the parameters to minimize the loss, thus improving the model's accuracy. This results in generating the neural network model 425, with no modifications to the neurons, as no faults have been detected in the IC.

When a fault is detected in an IC, the machine learning workflow 400B outputs a neural network model 440.

The neural network model 430 (original network) includes a plurality of neurons 432. A modified forward pass 434 feeds the neural network model 430 with the dataset 401. The forward pass is modified because a fault has been detected. For example, the first column of neurons has a different pattern to illustrate the modified neurons. The neurons have been modified by replacing or substituting certain operations or calculations with other operations or calculations. The substituted or replaced or swapped operations are equivalent or comparable to the original operations. The substituted or replaced or swapped operations can be referred to as approximated operations or calculations. The approximated operations or calculations are close to or roughly the same as the original operations or calculations, with slight variations or deviations or discrepancies. For all intents and purposes, such slight variations or deviations or discrepancies may be considered negligible or inconsequential or imperceptible when performing MAC unit operations in an AI accelerator designed to perform AI/ML processing. Thus, the accuracy of the neural network model can be maintained or preserved and can be considered acceptable, as the substituted neurons representing the slightly modified or altered operations or calculations are substantially equivalent to the original operations or calculations. As such, the neural network model 440 is an approximated model of the neural network model 430. For all intents and purposes, the neural network model 440 (approximated model) performs the operations or calculations in a substantially similar manner as the neural network model 440 (original model). The neural network model 440 (approximated model) substantially maintains the accuracy of the neural network model 440 (original model).

The output is fed into a loss function 436.

The errors from the loss function 436 are back propagated to the neural network model 430. The backward pass 438 involves calculating the gradients of the loss function 436 with respect to each weight and bias in the network, and then updating these parameters to minimize the loss.

The modified forward pass 434, the loss function 436, and the backward pass 438 work together to enable the neural network model 430 to learn from the dataset 401 and improve its performance. This results in generating the neural network model 440, with modifications to the neurons, as faults have been detected in the IC. The neural network model 440 is an approximated version of the neural network model 430. The neural network model 440, even though slightly modified, maintains an acceptable level of accuracy when running AI/ML processing using an AI accelerator.

Multiple models may be generated. Each model may focus on different faults or different combination of faults or different types of faults or different location of faults.

As a result, when another fault is detected in an IC, the machine learning workflow 400C outputs a neural network model 460.

The neural network model 450 (original network) includes a plurality of neurons 452. A modified forward pass 454 feeds the neural network model 450 with the dataset 401. The forward pass is modified because a fault has been detected. For example, the last columns of neurons have a different pattern to illustrate the modified neurons. The neurons have been modified by replacing or substituting certain operations or calculations with other operations or calculations. The substituted or replaced or swapped operations are equivalent or comparable to the original operations. The substituted or replaced or swapped operations can be referred to as approximated operations or calculations. The approximated operations or calculations are close to or roughly the same as the original operations or calculations, with slight variations or deviations or discrepancies. For all intents and purposes, such slight variations or deviations or discrepancies may be considered negligible or inconsequential or imperceptible when performing MAC unit operations in an AI accelerator designed to perform AI/ML processing. Thus, the accuracy of the neural network model can be maintained and can be considered acceptable, as the substituted neurons representing the slightly modified or altered operations or calculations are substantially equivalent to the original operations or calculations. As such, the neural network model 460 is an approximated model of the neural network model 450. For all intents and purposes, the neural network model 460 (approximated model) performs the operations or calculations in a substantially similar manner as the neural network model 450 (original model). The neural network model 460 (approximated model) substantially maintains the accuracy of the neural network model 450 (original model).

The output is fed into a loss function 456.

The errors from the loss function 456 are back propagated to the neural network model 450. The backward pass 458 involves calculating the gradients of the loss function 456 with respect to each weight and bias in the network, and then updating these parameters to minimize the loss.

The modified forward pass 454, the loss function 456, and the backward pass 458 work together to enable the neural network model 450 to learn from the dataset 401 and improve its performance. This results in generating the neural network model 460, with modifications to the neurons, as faults have been detected in the IC. The neural network model 460 is an approximated version of the neural network model 450. The neural network model 460, even though slightly modified, maintains an acceptable level of accuracy when running AI/ML processing using an AI accelerator.

Once all the modified neural network models (or approximated neural network models or equivalent neural network models) have been generated or created, the training phase 402 ends. The machine learning workflow 400 transitions from the training phase 402 to the inference phase 470.

In the inference phase 470, a fault map 472 is loaded (fault map loading 474). Each IC has a fault map 472. The fault map 472 is a visual or data-based representation that highlights the areas within the IC where faults are detected or predicted. The fault map 472 includes information about the type, location, and nature of faults. Different types of faults such as stuck-at faults, transition faults, bridging faults, open faults, and delay faults may be included. The fault map 472 may include information on the severity of the faults and their potential impact on the IC's functionality. By understanding where and why faults occur, manufacturers can implement process improvements to increase yield. In the instant case, the fault map of the IC is matched to a modified model to improve the yield.

Thus, after the fault map loading 474 is complete, a matching modified or approximated model (modified model match 476) is selected. The modified or approximated model is selected from the modified models generated from the training phase 402. In this example, the neural network model 440 is selected as the best match to the fault map 472 of the IC. The selected modified or approximated model is then loaded to the IC 100 (load mechanism 478 to load matching approximated model).

While an IC fault map provides a detailed, physical layout-based view of potential faults, a pre-trained neural network model offers a predictive, data-driven approximation of IC behavior under fault conditions. IC fault maps offer static analysis of potential defects in physical layout, whereas neural network models provide dynamic, predictive analysis of IC behavior based on training data. Fault maps provide accurate localization of faults but lack adaptability to new fault scenarios, whereas neural network models adapt to new scenarios but offer approximate rather than exact fault localization. By matching particular fault maps of ICs with approximated neural network models, both accuracy and adaptability may be achieved.

As such, the IC can be deployed and operated using the neural network model 440, which is a modified model or approximated model. Each IC can be deployed and operated with a different modified model or approximated model based on its fault map. Each IC includes different types of faults and different locations of faults, and thus, each IC has a different fault map associated with it. The generation of multiple modified models or approximated models in the training phase 402 allows for determining a best match between different IC fault maps and different modified models or approximated models. The modified or approximated models are incorporated in MAC units, which are incorporated in, e.g., an AI accelerator of an IC. The AI accelerator can thus employ AI/ML models or approximated AI/ML models with high accuracy.

AI/ML models are computational algorithms or mathematical frameworks that enable machines to learn from data and make predictions or decisions without explicit programming. These models form the foundation of various AI applications and systems, ranging from image recognition and natural language processing to autonomous vehicles and recommendation systems.

The main components of AI/ML models include data, features, algorithms, training, evaluation, and inference.

AI/ML models rely on data to learn patterns, relationships, and insights. The quality, quantity, and diversity of data significantly impact the performance and effectiveness of the model. Features are the input variables or attributes extracted from the data that the model uses to make predictions or classifications. Feature engineering involves selecting, transforming, and preprocessing relevant features to improve model accuracy. Machine learning algorithms are mathematical techniques or procedures used to train AI models on data and optimize their parameters to minimize errors or maximize performance. Common ML algorithms include linear regression, decision trees, support vector machines, and neural networks.

Model training involves feeding labeled data (i.e., training data or training examples) into the algorithm and adjusting the model's parameters iteratively to minimize the difference between predicted outputs and actual outputs. Training typically involves techniques such as gradient descent and backpropagation for optimizing parameters. Once trained, the AI/ML models are evaluated on a separate dataset (validation or test set) to assess their performance, generalization ability, and accuracy. Metrics such as accuracy, precision, recall, and area under the curve (AUC) are commonly used to evaluate model performance.

Inference is the process of using a trained model to make predictions or classifications on new, unseen data. During inference, the model applies the learned patterns to new inputs and generates predictions or outputs.

The example embodiments may use any types of AI/ML models. For example, the models may include supervised learning, unsupervised learning, reinforcement learning, deep learning, and/or transfer learning.

In supervised learning, the model is trained on labeled data, where each input example is associated with a corresponding target or output. The model learns to map inputs to outputs and can make predictions on unseen data. Examples include classification and regression tasks.

Unsupervised learning involves training the model on unlabeled data to identify patterns, clusters, or structures within the data. The model learns to uncover hidden relationships or groupings without explicit guidance. Examples include clustering, dimensionality reduction, and anomaly detection.

Reinforcement learning (RL) involves training an agent to interact with an environment and learn optimal actions or policies to maximize cumulative rewards. RL algorithms learn through trial and error, receiving feedback from the environment based on actions taken.

Deep learning is a subset of machine learning that uses artificial neural networks with multiple layers (deep architectures) to learn complex patterns from data. Deep learning excels in tasks such as generative modeling.

Transfer learning involves leveraging knowledge or features learned from one task or domain to improve performance on a related task or domain. Pre-trained models are fine-tuned or adapted to new datasets or tasks with limited labeled data.

Any of these types of AI/ML models may be used by the AI accelerator 120.

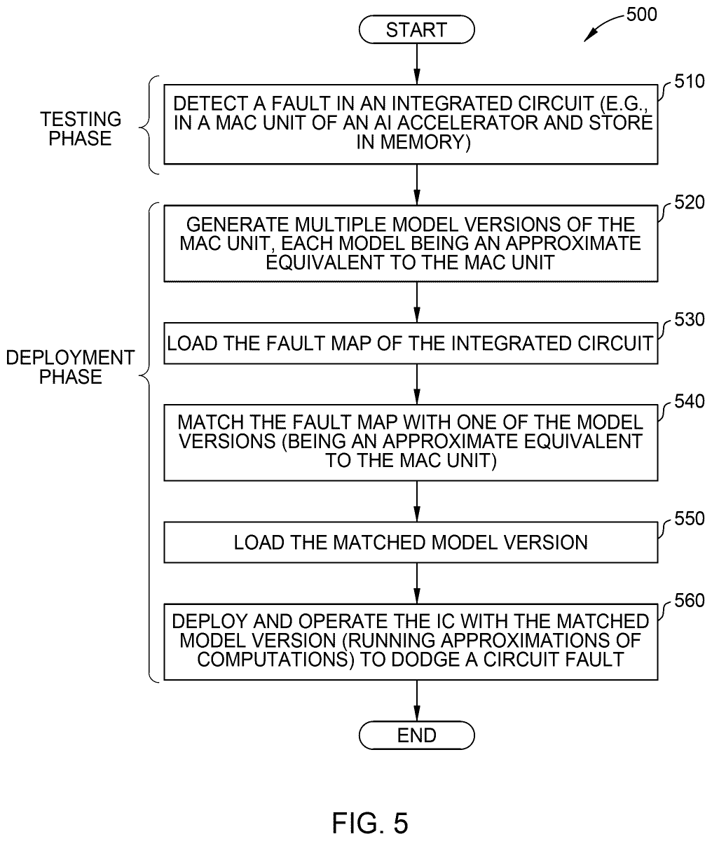

FIG. 5 illustrates a method for running an approximated equivalent model in the ICs, according to an example.

At block 510, a fault is detected in an integrated circuit (e.g., in a MAC unit of an AI accelerator). The fault is detected in a testing phase. A fault may can be stored in memory for every device. Common faults include stuck-at faults, bridging faults, open faults, and transient faults. Stuck-at faults occur when a signal line is stuck at a logical high or a logical low. Bridging faults occur when there is an unintended connection between two signal lines. Open faults occur when a connection is broken and transient faults occur when temporary errors are detected due to, e.g., external interference. Faults can originate from manufacturing defects, material imperfections, design errors, or environmental factors, such as temperature variations.

At block 520, multiple model versions of the MAC unit are generated, each model being an approximate equivalent to the MAC unit. A pre-trained neural network model refers to a machine learning model trained to approximate the behavior of a faulty IC or specific fault conditions. This model learns from data collected from various fault scenarios and can predict the behavior of the IC under new or unseen fault conditions. The pre-trained neural network model is an approximated model allowing the IC to operate in the approximated mode.

At block 530, the fault map of the integrated circuit is loaded. The IC fault map is a detailed representation that identifies potential faults within an integrated circuit. The IV fault map provides a structured view of where faults may occur, categorized by type (such as stuck-at faults, bridging faults, etc.), and their physical locations on the IC layout. This map is typically generated during the design phase or through extensive testing and validation processes.

At block 540, the fault map is matched with one of the model versions (being an approximate equivalent to the MAC unit). Thus, after the fault map loading is complete, a matching modified model is selected. The modified model is selected from the modified models generated from the training phase. Each IC includes a different fault map. By generating multiple approximated models, a best match can be achieved between the fault of the particular IC and a generated approximated model.

At block 550, the matched model version is loaded. The approximated model is loaded on the IC and the IC can be deployed and operated with such approximated neural network model with acceptable accuracy.

At block 560, the IC is deployed and operated with the matched model version (running approximations of computations) to dodge or avoid or bypass a circuit fault. Thus, even though the IC may include faults, the IC can be salvaged, providing increased yield. Blocks 520-560 may be referred to as a deployment phase.

The benefits of IP harvesting or salvaging include at least reducing the cost associated with developing new IP from scratch, speeding up the development process by reusing existing, proven IP, and increasing the effective yield by making use of partially functional chips. By salvaging functional parts from defective AI accelerators, companies can reduce the need to manufacture new components from scratch, leading to significant cost savings. Reusing proven and tested components decreases the expenses associated with developing new AI accelerators, including design, prototyping, and testing costs. Salvaging allows for the reuse of valuable components, such as processing units, memory modules, and power supplies, maximizing the utilization of existing assets. Utilizing salvaged parts also helps in managing inventory more efficiently by reducing the stockpile of unused or obsolete components.

In conclusion, a fault-aware training mechanism is used to salvage MAC units or AI accelerators by adapting the training of neural networks to account for the presence of faults in the hardware. The goal is to create an approximated equivalent of the MAC unit that can function correctly despite the presence of certain faults. To mitigate the impact of faulty MAC units, a fault-aware training mechanism can be used that generates multiple approximated neural networks to be resilient to hardware faults. Approximate computing leverages the idea that not all computations need to be exact, especially in applications like neural networks where slight inaccuracies can be tolerated.

The example embodiments present a way to utilize AI accelerators with defective tiles without compromising the reliability of the results, nor incurring tedious retraining costs by presenting innovative approaches to allow practical AI accelerator salvaging without the need for tedious per-chip retraining. One approach is a hardware fault-tolerant approach and another approach is a software fault-tolerant approach. Both proposed methodologies allow dynamic adaptation to aging defects, leading to prolonged device lifetime. The approaches involve generating approximated neural network models incorporated into MAC units of AI accelerators of ICs.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. A method comprising:
generating multiple neural network model approximations of a compute engine of an integrated circuit (IC) including at least one fault;
matching a fault map loaded to the IC with one of the multiple neural network model approximations; and
loading a matched neural network model approximation to the IC.

2. The method of claim 1, wherein the compute engine is a multiply-accumulate (MAC) unit incorporated within an artificial intelligence (AI) accelerator.

3. The method of claim 1, wherein the multiple neural network model approximations are generated when the compute engine transitions into an approximate mode.

4. The method of claim 3, wherein, in the approximate mode, a first set of operations are substituted for a second set of operations.

5. The method of claim 4, wherein the first set of operations are higher precision arithmetic operations and the second set of operations are lower precision arithmetic operations.

6. The method of claim 1, wherein the multiple neural network model approximations are generated in a training phase of a machine learning workflow.

7. The method of claim 1, wherein the fault map is matched with one of the multiple neural network model approximations in an inference phase of a machine learning workflow.

8. The method of claim 1, wherein the at least one fault is present in one or more columns of neurons of the multiple neural network model approximations.

9. A method comprising:
operating an integrated circuit (IC) having a fault and loaded with a matched neural network model approximation that is selected by:
transitioning a compute engine of the IC into an approximate mode; and
substituting a first set of operations for a second set of operations.

10. The method of claim 9, wherein the first set of operations are higher precision arithmetic operations and the second set of operations are lower precision arithmetic operations.

11. The method of claim 9, wherein the matched neural network model approximation allows bypassing the fault of the IC.

12. The method of claim 9, wherein the compute engine is a multiply-accumulate (MAC) unit incorporated within an artificial intelligence (AI) accelerator.

13. A system comprising:
at least one physical processor; and
physical memory comprising computer-executable instructions that, when executed by the physical processor, cause the physical processor to:
generate multiple neural network model approximations of a compute engine of an integrated circuit (IC) including at least one fault;
load a fault map of the IC;
match the fault map of the IC with one of the multiple neural network model approximations; and
load a matched neural network model approximation to the IC.

14. The system of claim 13, wherein the compute engine is a multiply-accumulate (MAC) unit incorporated within an artificial intelligence (AI) accelerator.

15. The system of claim 13, wherein the multiple neural network model approximations are generated when the compute engine transitions into an approximate mode.

16. The system of claim 15, wherein, in the approximate mode, a first set of operations are substituted for a second set of operations.

17. The system of claim 16, wherein the first set of operations are higher precision arithmetic operations and the second set of operations are lower precision arithmetic operations.

18. The system of claim 13, wherein the multiple neural network model approximations are generated in a training phase of a machine learning workflow.

19. The system of claim 13, wherein the fault map is matched with one of the multiple neural network model approximations in an inference phase of a machine learning workflow.

20. The system of claim 13, wherein the at least one fault is present in one or more columns of neurons of the multiple neural network model approximations.
